(19) United States
(12) Patent Application Publication
(10) Pub. No.: US 2009/0065940 A1
(43) Pub. Date: Mar. 12, 2009

(54) METAL WIRING OF A SEMICONDUCTOR DEVICE AND METHOD OF FORMING THE SAME

(75) Inventors: Eun Soo Kim, Incheon-Si (KR); Cheol Mo Jeong, Icheon-si (KR); Seung Hee Hong, Seoul (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Icheon-si (KR)

(21) Appl. No.: 11/951,379

(22) Filed: Dec. 6, 2007

(30) Foreign Application Priority Data
Sep. 6, 2007 (KR) 10-2007-90290

(51) Int. Cl. H01L 23/522; H01L 21/768

(52) U.S. Cl. 257/754; 257/774; 438/637; 257/E23.145; 257/E21.575

(57) ABSTRACT

According to a method of forming a metal wiring of a semiconductor device, a contact plug is formed at height lower than the contact hole, which is formed on an interlayer insulation layer, and then a metal wiring is formed over the contact plug and interlayer insulation layer to completely fill inside of the contact hole, decreasing process difficulty, ensuring reproducibility, and improving electrical property.

### CROSS-REFERENCES TO RELATED APPLICATIONS

The priority of Korean patent application number 10-2007-90290, filed on Sep. 6, 2007, is hereby claimed and its disclosure is incorporated by reference herein in its entirety.

### BACKGROUND OF THE INVENTION

The present invention relates to a metal wiring of a semiconductor device and method of forming the same, and more particularly to a metal wiring of a semiconductor device and method of forming the same with low resistance, improving electrical characteristics.

Typically, a metal wiring is formed on a semiconductor device for electrically connecting a transistor or memory cell formed on a semiconductor substrate to peripheral circuits. The metal wiring is formed over an interlayer insulation layer and connected to the transistor or peripheral circuits through a contact plug. A contact hole is formed on the interlayer insulation layer and then the contact plug is formed within the contact hole. As the degree of integration of semiconductor devices becomes higher, the width of the contact hole becomes narrower. When the depth of the contact hole is kept constant and the width thereof becomes narrower, the aspect ratio increases. As a result, voids can be formed while filling the contact hole with a conductive substance to form a contact plug inside the contact hole. As the width of the contact hole becomes narrower and narrower, the ratio of the inside of the contact hole occupied by the voids increases. Therefore, the resistance of the contact plug increases. Moreover, the voids are exposed while performing a chemical and mechanical polishing process such that a conductive material layer is formed to fill the contact hole and the conductive material remains only inside the contact hole. Additionally, H₂O₂ contained in slurry that is used in the polishing process penetrates into the voids and thus the conductive material layer may be removed excessively. In this case, in a subsequent process, the metal wiring is connected abnormally to the contact plug and thus resistance increases abruptly, or is not connected to the contact plug and thus causes a failure.

### BRIEF SUMMARY OF THE INVENTION

According to a metal wiring of a semiconductor substrate and a method of forming the same disclosed herein, the contact plug is formed at lower height than the contact hole, which is formed on the interlayer insulation layer, and then a metal wiring is formed over the contact plug and interlayer insulation layer. The method and apparatus can have one or more advantages, such as completely filling the inside of the contact hole, decreasing process difficulty, ensuring reproducibility, and improving one or more electrical properties.

A metal wiring of a semiconductor substrate according to an embodiment of the present invention comprises a contact hole formed on a interlayer insulation layer over a semiconductor substrate and exposing a bonding region, a contact plug formed inside of the contact hole and having lower height than the interlayer insulation layer, a metal wiring formed on the interlayer insulation layer and filling the contact hole on the top of the contact plug, and a bonding layer formed between the contact plug and the metal wiring.

The metal wiring preferably further comprises an etching mask formed between the interlayer insulation layer and semiconductor substrate.

The metal wiring preferably further comprises a barrier metal layer formed between the contact plug and interlayer insulation layer.

Preferably, the middle of the contact plug is concave and the edge thereof protrudes upwards within the contact hole.

The bonding layer is preferably in amorphous state, and comprises a metal silicide layer. The metal silicide layer is preferably an amorphous metal silicide layer, and comprises a tungsten silicide layer.

A method of forming metal wiring of a semiconductor substrate according to an embodiment of the present invention comprises steps of forming a contact hole formed in a interlayer insulation layer over a semiconductor substrate, forming a contact plug inside of the contact hole and having lower height than the interlayer insulation layer, forming a first conductive layer on the semiconductor substrate including a bonding layer to fill the contact hole over the contact plug, and forming a metal wiring connected electrically to the contact plug by patterning the first conductive layer and bonding layer.

An etching mask preferably is further formed between the interlayer insulation layer and the semiconductor substrate.

The step of forming the contact plug further preferably comprises forming a second conductive layer on the semiconductor substrate to fill the contact hole, and etching the second conductive layer over the interlayer insulation layer to remain only inside of the contact hole.

The second conductive layer preferably includes tungsten.

The etching step preferably is performed using an etching back process, and preferably the etching process is performed excessively for the second conductive layer to remain inside of the contact hole at height lower than the interlayer insulation layer.

Preferably, a step of forming barrier metal layer along the surface of the interlayer insulation layer including the contact plug is performed, before forming the second conductive layer.

The etching process is performed preferably until the barrier metal layer over the interlayer insulation layer is removed, and the etching process is performed preferably on the condition that the second conductive layer is etched preferably more than the barrier metal layer.

The top of the second conductive layer is preferably etched into a concave form by the etching process.

The contact plug remains preferably at 10% to 30% of the height of the interlayer insulation layer.

The bonding layer is formed preferably in an amorphous state. The bonding layer preferably comprises a metal silicide layer. The metal silicide layer preferably includes a tungsten silicide layer. The bonding layer is formed preferably using PVD method.

The first conductive layer preferably is formed using a PVD method, and preferably includes tungsten. The bonding layer and first conductive layer preferably are formed in-situ within the same depositing equipment and by the same process.

The first conductive layer is patterned preferably with a protective layer being formed thereon. The contact plug and first conductive layer are formed preferably of the same material, and the contact hole preferably is formed over the top of a source contact plug and a bonding region of a peripheral circuit.

As described above, the contact plug preferably is formed at lower height than the contact hole, which is formed on the interlayer insulation layer, and then a metal wiring is formed over the contact plug and interlayer insulation layer to completely fill the inside of the contact hole, and thereby provide one or more benefits such as decreasing process difficulty, ensuring reproducibility, and improving one or more electrical properties.

In particular, in one embodiment a chemical and mechanical polishing process can be omitted when forming a contact plug, and thus excessive polishing of the contact plug can be avoided. Furthermore, in the same or another embodiment, surface resistance of the metal wiring can be reduced using a metal silicide layer under the metal wiring.

In the following, the preferred embodiment of the present invention will be described with reference to the accompanying drawings. However, the present invention is not limited to the embodiments disclosed later and can be embodied by various forms and thus the scope of the present invention is not defined as the following embodiments. The scope of the present invention will be understood by the claims.

Meanwhile, when it is described that one layer is “over” of another layer, the one layer can exist contacting directly to another layer or semiconductor substrate, or one or more other layers can interpose therebetween. Additionally, in the drawings, the thickness and size of each layer are exaggerated for a convenient explanation. In the drawings, common reference numerals refer to common elements.

### BRIEF DESCRIPTION OF THE DRAWINGS

The accompanying drawings, which are included to provide a further understanding of the invention and are incorporated in and constitute a part of this application, illustrate embodiments of the invention and together with the description assist in explaining the principle of the invention. In the drawings:

FIGS. 1A to 1H are sectional views illustrating methods of forming the metal wiring of a semiconductor device according to embodiments of the present invention.

### DESCRIPTION OF SPECIFIC EMBODIMENTS

Reference will now be made in detail to the preferred embodiments of the present invention, examples of which are illustrated in the accompanying drawings.

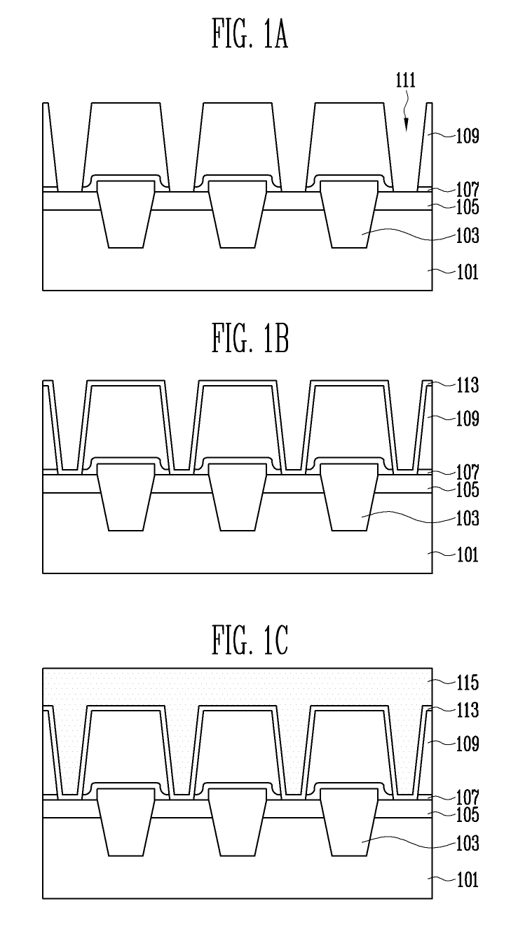

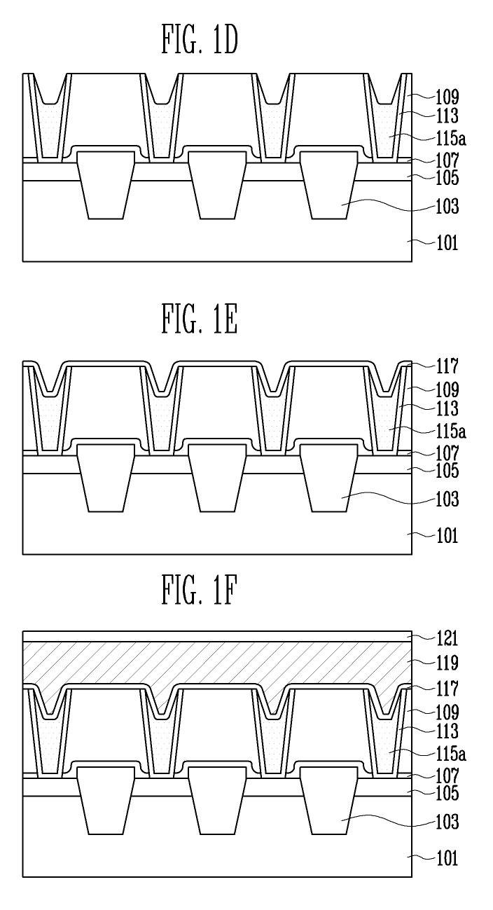

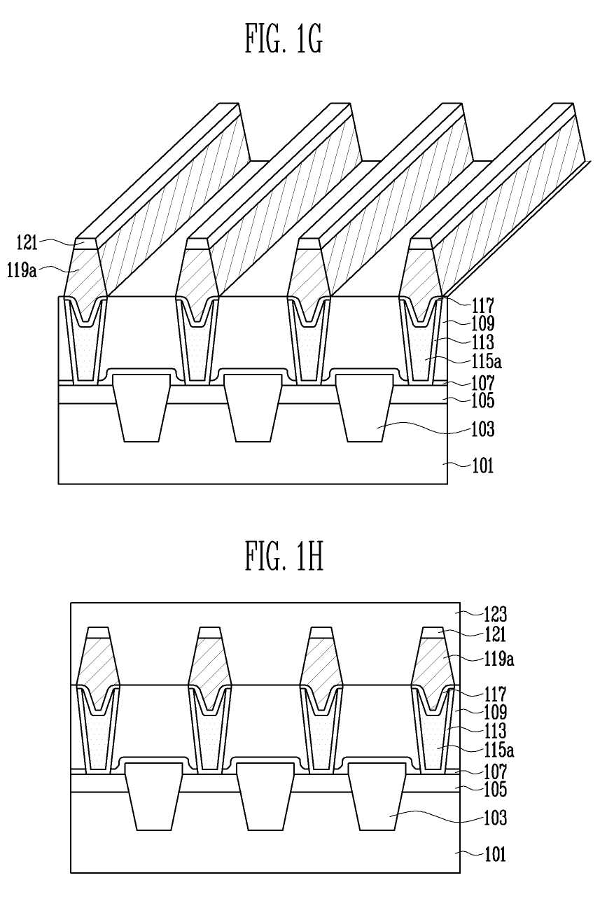

Referring to FIG. 1A, an isolation layer element 103 is formed on an isolation region element of a semiconductor substrate 101 and a bonding region 105 and a gate (not shown) of a transistor or memory cell are formed on a part of an active region. The isolation layer element 103 is preferably formed in a shallow trench isolation (STI) structure.

In case of NAND flash memory element, a plurality of the isolation layer elements 103 is formed in parallel on a cell region, and an active region is defined as the semiconductor substrate 101 between the isolation layer elements 103. Additionally, a plurality of word lines and select lines (not shown) is formed on the semiconductor substrate 101 to intersect the isolation layer element 103, and a bonding region 105 is formed on the semiconductor substrate 101 between the word lines and select lines. The bonding region 105 shown in FIG. 1A may be a drain that is formed between drain select lines of a NAND flash memory element.

An etching mask 107 and first interlayer insulation layer 109 are formed subsequently on the semiconductor substrate 101 including the bonding region 105. The etching mask 107 is formed to avoid an exposure of gate, word line or select line when an alignment error occurs in a subsequent etching process in order to form a contact hole, and is referred to as a self align contact (SAC) insulation layer. This etching mask 107 has a different etching selection ratio from the first interlayer insulation layer 109, and may be formed as a nitride layer.

Next, the first interlayer insulation layer 109 and etching mask 107 are removed subsequently to an extent to expose the bonding region 105 to form a contact hole 111. Since the drain 105 is formed repeatedly on the semiconductor substrate 101 between the element isolation layer 103 in case of NAND flash memory element, the contact hole 111 may be formed in lines at a constant interval. Additionally, in the case of a NAND flask memory element, before the first interlayer insulation layer 109 is formed, first, a source contact plug (not shown in a current sectional view) is formed, and the contact hole 111 is formed over the source contact plug and thus the source contact plug may be exposed as well. Moreover, in the peripheral circuit region, the peripheral circuit may be exposed as well. Processes for forming a source contact plug are known in the prior art, and a detailed description thereof is omitted.

Referring to FIG. 1B, a barrier metal layer 113 is formed over the first interlayer insulation layer 109 including the bonding region 105 exposed to the bottom of the contact hole 111. The barrier metal layer 113 preferably is a single film formed of Ti or TiN, however, it may include laminated films including Ti or TiN.

Referring to FIG. 1C, a first conductive layer 115 is formed over the barrier metal layer 113 to completely fill the contact hole 111. The first conductive layer 115 may be formed of copper, aluminum, tungsten, platinum or ruthenium and hereinafter a case of using tungsten will be described. The first conductive layer 115 is formed preferably using a CVD method, LP-CVD method or PE-CVD method, which has an excellent step coverage property, rather than a PVD method. When the first conductive layer 115 is formed using a CVD method, an over hang (not shown) can occur on the top edge of the contact hole 111 in the course of forming the first conductive layer 115 and thus the entrance of the contact hole 111 can be covered before the inside of the contact hole 111 is filled with the first conductive layer 115. As a result, voids or a seam may be formed on the inside of the contact hole 111.

Referring to FIG. 1D, the first conductive layer 115 over the first interlayer insulation layer 109 is partially removed and etched to remain only inside of the contact hole 111, forming a contact plug 115a made of the first conductive layer material. In case of a NAND flash memory element, the contact plug 115a becomes a drain contact plug.

To remove the first conductive layer 115 over the first interlayer insulation layer 109, a chemical and mechanical polishing process may be used. However, while polishing the first conductive layer 115, a void may be exposed and H₂O₂ in slurry used in the polishing process may contact the first conductive layer 115 that is exposed in large area through the void and thus the first conductive layer 115 may be removed excessively.

To avoid this excessive removal, the first conductive layer 115 is preferably etched-back. The etching-back process of the first conductive layer 115 preferably is performed excessively to remove the barrier metal layer 113 over the first interlayer insulation layer 109. The etching-back process of the first conductive layer 115 may end at the moment of removing the barrier metal layer 113 over the first interlayer insulation layer 109. Since the barrier metal layer 113 has a different etching selection ratio from the first conductive layer 115, a greater amount of the top part of the first conductive layer 115 is etched inside of the contact hole 111 while removing the barrier metal layer 113. As described above, the top part of the first conductive layer 115 is etched inside of the contact hole 111 and the contact plug 115a is formed only on the lower part of the contact hole 111. More specifically, the process condition of the etching back process is preferably set for the contact plug 115a to be formed at 10% to 30% of the height of the first interlayer insulation layer 109 when compared the middle height of the contact plug 115a and the top height of the first interlayer insulation layer 109 from the surface of the overall semiconductor substrate 101. It is possible to control the sorts of etching gas or amount of supplying fluid, etc.

Meanwhile, when the first conductive layer 115 is etched-back, a void (seam) if present inside of the first conductive layer 115 is exposed to form a trench in the middle thereof and the first conductive layer 115 remains on the side wall of the contact hole 111. Accordingly, the barrier metal layer 113 is protected by the first conductive layer 115 and thus remains on substantially all of the side wall of the contact hole 111.

Referring to FIG. 1E, a bonding layer 117 is formed over the first interlayer layer 109 including the contact plug 115a. The bonding layer 117 may be formed as a metal silicide layer, and the bonding layer 117 is preferably formed as a tungsten silicide layer in case of the contact plug 115a being formed of tungsten. Moreover, the bonding layer 117 is formed preferably in an amorphous state using PVD method. The object of forming the bonding layer 117 and the reason of using PVD method are described below.

Referring to FIG. 1F, a second conductive layer 119 and protective layer 121 are formed on the semiconductor substrate 101 including the bonding layer 117. The second conductive layer 119 is intended to compensate the decreased height of the contact plug 115a by an excessive etching back process, and to form metal wiring (or bit line). In addition, the protective layer 121 serves to avoid etching loss (particularly, plasma damage) to the second conductive layer 119 in a subsequent etching process of the second conductive layer 119.

The second conductive layer 119 may be formed of copper, aluminum, tungsten, platinum or ruthenium, and is preferably formed of the same material (particularly, tungsten) as the contact plug 115a. In addition, the second conductive layer 119 is formed preferably to have thickness enough to completely fill the contact hole 111 over the contact plug 115a and be deposited thickly on the top of the first interlayer insulation layer 109. For example, the second conductive layer 119 is formed to be deposited on the top of the first interlayer insulation layer 109 in a thickness in a range of about of 800 Å to about 1200 Å, using a PVD method. When the bonding layer 117 is formed using a PVD method in a prior process, the bonding layer 117 and second conductive layer 119 may be formed continuously, in-situ within the same depositing equipment.

When the bonding layer 117 is formed using a PVD method, it may be formed in an amorphous state to improve bonding to the contact plug 115a, and then the second conductive layer 119 can be formed over the bonding layer 117 in-situ to form the second conductive layer 119 with low surface resistance. When the second conductive layer 119 is formed using a PVD method, since it is formed over the bonding layer 117 of amorphous state, the grain size of the second conductive layer 119 increases to reduce resistance, compared to the case of forming it without the bonding layer 117.

Meanwhile, the protective layer may be formed as a nitride layer, and when it is formed using a PVD method, it may be formed in-situ, together with the second conductive layer 119.

Referring to FIG. 1G, the protective layer 121 and second conductive layer 119 are patterned by an etching process to form metal wiring (or bit line) 119a. The first interlayer insulation layer 109 is exposed between the metal wirings 119a.

Referring to FIG. 1H, a second interlayer insulation layer 123 is formed over the first interlayer insulation layer 109 including the metal wiring 119a. The second interlayer insulation layer 123 may be formed to have thickness enough to completely cover the metal wiring 119a.

As metal wirings are formed as described above, the contact plug 115a, which is connected to the bonding region 105 and has lower height than the interlayer insulation layer 109, is formed inside the contact hole 111 of the interlayer insulation layer 109. The contact plug 115a can be formed in such a way as the top of the plug is concave. Additionally, the metal wiring 119a is formed over the interlayer insulation layer 109 to completely fill the contact hole 111 over the contact plug 115a.

What is claimed is:

1. A metal wiring of a semiconductor device comprising:
a contact hole formed in an interlayer insulation layer over a semiconductor substrate and exposing a bonding region;
a contact plug formed inside of the contact hole and having height lower than the interlayer insulation layer;
a metal wiring formed on the interlayer insulation layer and filling the contact hole on top of the contact plug; and
a bonding layer formed between the contact plug and metal wiring.

2. A metal wiring of a semiconductor device according to claim 1, further comprising a barrier metal layer formed between the contact plug and interlayer insulation layer.

3. A metal wiring of a semiconductor device according to claim 1, wherein the middle of the contact plug is concave and the edge thereof protrudes upwards within the contact hole.

4. A metal wiring of a semiconductor device according to claim 1, wherein the bonding layer is in an amorphous state.

5. A metal wiring of a semiconductor device according to claim 1, wherein the bonding layer comprises a metal silicide layer.

6. A metal wiring of a semiconductor device according to claim 5, wherein the metal silicide layer is an amorphous metal silicide layer.

7. A metal wiring of a semiconductor device according to claim 5, wherein the metal silicide layer comprises a tungsten silicide layer.

8. A method of forming a metal wiring of a semiconductor substrate comprising steps of:
forming a contact hole on a interlayer insulation layer over a semiconductor substrate having a bonding layer;
forming a contact plug inside of the contact hole with a height lower than the interlayer insulation layer;
forming a first conductive layer on the semiconductor substrate including the bonding layer to fill the contact hole over the contact plug; and
forming a metal wiring connected electrically to the contact plug by patterning the first conductive layer and the bonding layer.

9. A method of forming a metal wiring of a semiconductor substrate according to claim 8, wherein the step of forming the contact plug comprises:
forming a second conductive layer on the semiconductor substrate to fill the contact hole; and
etching the second conductive layer over the interlayer insulation layer to remain only inside of the contact hole.

10. A method of forming a metal wiring of a semiconductor substrate according to claim 9, comprising forming the second conductive layer of a material comprising tungsten.

11. A method of forming a metal wiring of a semiconductor substrate according to claim 9, comprising performing the etching step using an etching back process.

12. A method of forming a metal wiring of a semiconductor substrate according to claim 9, comprising performing the etching process excessively for the second conductive layer to remain inside of the contact hole at height lower than the interlayer insulation layer.

13. A method of forming a metal wiring of a semiconductor substrate according to claim 9, further comprising forming a barrier metal layer along the surface of the interlayer insulation layer including the contact plug before forming the second conductive layer.

14. A method of forming a metal wiring of a semiconductor substrate according to claim 13, comprising performing the etching process until the barrier metal layer over the interlayer insulation layer is removed.

15. A method of forming a metal wiring of a semiconductor substrate according to claim 14, comprising etching the second conductive layer more than the barrier metal layer.

16. A method of forming a metal wiring of a semiconductor substrate according to claim 9, comprising etching the top of the second conductive layer into a concave form.

17. A method of forming a metal wiring of a semiconductor substrate according to claim 8, comprising forming the bonding layer in an amorphous state.

18. A method of forming a metal wiring of a semiconductor substrate according to claim 17, comprising forming the bonding layer of a material comprising a metal silicide layer.

19. A method of forming a metal wiring of a semiconductor substrate according to claim 18, wherein the metal silicide layer includes a tungsten silicide layer.

20. A method of forming a metal wiring of a semiconductor substrate according to claim 8, comprising forming the bonding layer using a PVD method.

21. A method of forming a metal wiring of a semiconductor substrate according to claim 8, comprising forming the first conductive layer using a PVD method.

22. A method of forming a metal wiring of a semiconductor substrate according to claim 21, comprising forming the first conductive layer of a material comprising tungsten.

23. A method of forming a metal wiring of a semiconductor substrate according to claim 8, comprising forming the bonding layer and first conductive layer in-situ within same depositing equipment and using the same process.

24. A method of forming a metal wiring of a semiconductor substrate according to claim 9, comprising patterning the first conductive layer with a protective layer being formed thereon.

25. A method of forming a metal wiring of a semiconductor substrate according to claim 9, comprising forming the contact plug and the first conductive layer of the same material.
